(19) United States
(12) Patent Application Publication
(10) Pub. No.: US 2025/0318239 A1
(43) Pub. Date: Oct. 9, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Kazuki MINAMIKAWA, Nomi Ishikawa (JP)

(21) Appl. No.: 18/821,671

(22) Filed: Aug. 30, 2024

(30) Foreign Application Priority Data
Apr. 3, 2024 (JP) 2024-060327

(51) Int. Cl. H01L 29/423; H01L 29/739

(52) U.S. Cl. CPC H10D 64/281; H10D 12/481

(57) ABSTRACT

According to one embodiment, a semiconductor device has first and second electrodes with a semiconductor layer therebetween. An insulating layer is between the first electrode and the semiconductor layer. A gate electrode is adjacent to a mesa part of the semiconductor layer. A conductive member is also adjacent to the mesa part. A first connector is between the first electrode and the mesa part at a first position. A second connector is between the first electrode and the first conductive member at a second position. The first electrode has a first recess above the first conductive member at the first position. The first position and the second position are offset from each other in a length direction.

### CROSS-REFERENCE TO RELATED APPLICATION

This application is based upon and claims the benefit of priority from Japanese Patent Application No. 2024-060327, filed Apr. 3, 2024, the entire contents of which are incorporated herein by reference.

### FIELD

Embodiments described herein relate generally to a semiconductor device.

### BACKGROUND

Some vertical power devices having a trench-gate structure include a dummy trench, which does not function as a gate electrode.

### BRIEF DESCRIPTION OF THE DRAWINGS

FIG. 1 is a schematic plan view of a semiconductor device according to a first embodiment.

FIG. 2 is a cross-sectional view taken along line A-A in FIG. 1.

FIG. 3 is a schematic plan view of a semiconductor device according to a second embodiment.

FIG. 4 is a cross-sectional view taken along line B-B in FIG. 3.

FIG. 5 is a graph depicting simulation results of related to an amount of warpage of a wafer.

### DETAILED DESCRIPTION

Embodiments concern reduced warpage in a semiconductor device.

In general, according to one embodiment, a semiconductor device includes a first electrode, a second electrode, and a semiconductor layer between the first electrode and the second electrode. The semiconductor layer has a plurality of mesa parts spaced from each other in a first direction. An insulating layer is between the first electrode and the semiconductor layer. A gate electrode is adjacent in the first direction to a first mesa part in the plurality of mesa parts and extends lengthwise in a second direction perpendicular to the first direction. A first conductive member is also adjacent in the first direction to the first mesa part. The first mesa part is between the gate electrode and the first conductive member in the first direction and extends lengthwise in the second direction. A first connector is between the first electrode and the first mesa part at a first position along the second direction and electrically connects the first electrode and the first mesa part. A second connector is between the first electrode and the first conductive member at a second position along the second direction and electrically connects the first electrode and the first conductive member. The first electrode has a first recess above the first conductive member at the first position along the second direction. The first position and the second position are offset from each other in the second direction.

### First Embodiment

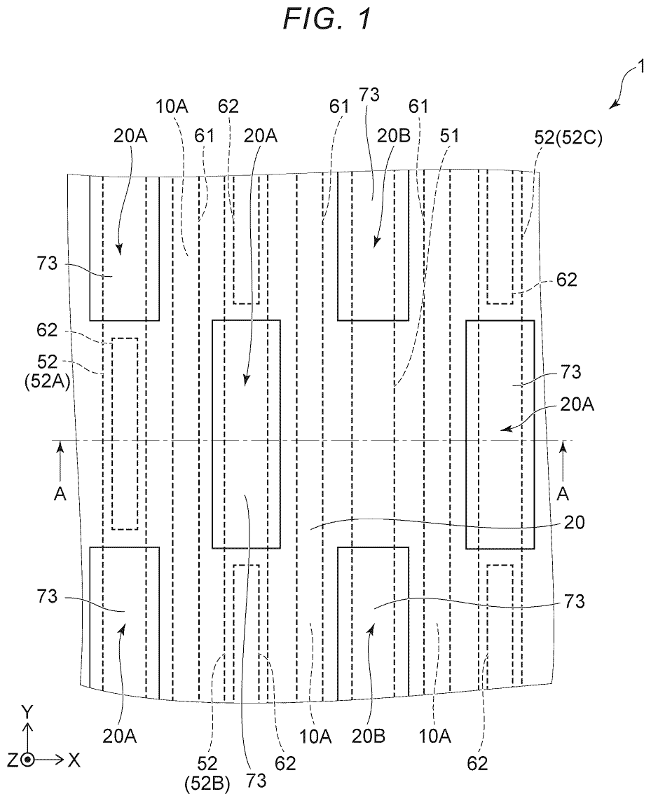

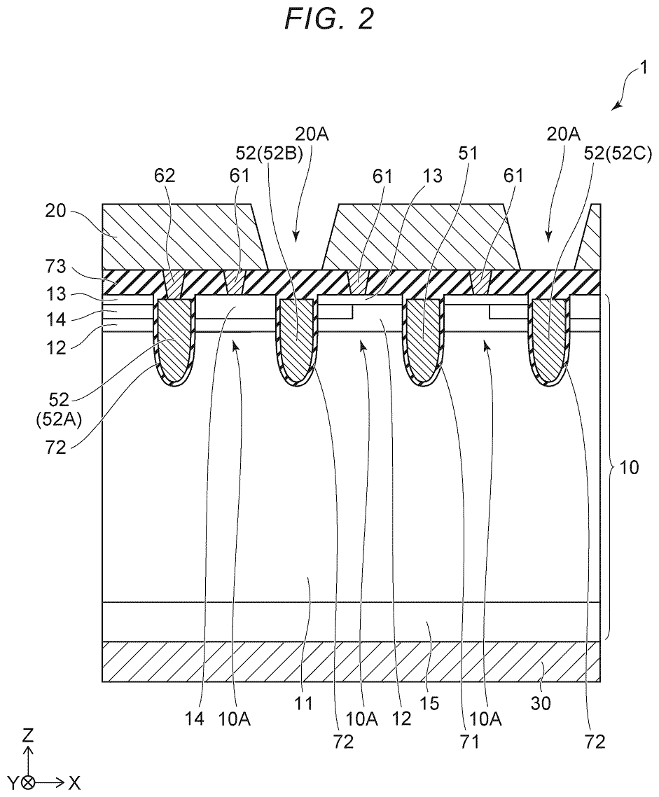

A semiconductor device 1 according to the first embodiment will be described with reference to FIGS. 1 and 2. The semiconductor device 1 includes a first electrode 20, a second electrode 30, and a semiconductor layer 10.

The semiconductor device 1 has, for example, an insulated gate bipolar transistor (IGBT) structure. The first electrode 20 is an emitter electrode in the IGBT, and the second electrode 30 is a collector electrode in the IGBT. For example, a positive voltage is applied to the second electrode 30, and a ground voltage is applied to the first electrode 20. In an on state in which a gate voltage of a gate electrode 51 is higher than a threshold voltage, a current flows between the first electrode 20 and the second electrode 30 in the vertical direction (direction Z) through the semiconductor layer 10. Along the direction Z, for descriptive convenience, the direction going from the second electrode 30 to the first electrode 20 can be referred to as up or upward, and the direction going from the first electrode 20 to the second electrode 30 is referred to as down or downward.

The semiconductor layer 10 is positioned between the first electrode 20 and the second electrode 30 in the direction Z. The semiconductor layer 10 includes a plurality of mesa parts 10A arranged along the direction X. The semiconductor layer 10 extends in the direction Y. The direction X and the direction Y are orthogonal to each other in a plane orthogonal to the direction Z. The semiconductor layer 10 is a silicon layer, for example. The semiconductor layer 10 may be a silicon carbide layer or gallium nitride layer. In the present example, for the conductivity type of the semiconductor layer 10, a first conductivity type is described as n-type and a second conductivity type is described as p-type. However, in other examples, the first conductivity type may be p-type and the second conductivity type may be n-type.

The semiconductor layer 10 includes an n-type first semiconductor layer 11, a p-type second semiconductor layer 12 located on the first semiconductor layer 11, and an n-type third semiconductor layer 13 located on the second semiconductor layer 12. The n-type impurity concentration of the third semiconductor layer 13 is greater than the n-type impurity concentration of the first semiconductor layer 11. The semiconductor layer 10 further includes a p-type fifth semiconductor layer 15 located between the second electrode 30 and the first semiconductor layer 11. The p-type impurity concentration of the fifth semiconductor layer 15 is greater than the p-type impurity concentration of the second semiconductor layer 12. The fifth semiconductor layer 15 contacts the second electrode 30 and is electrically connected to the second electrode 30.

The first semiconductor layer 11, the second semiconductor layer 12, the third semiconductor layer 13, and the fifth semiconductor layer 15 correspond to a drift layer, a base layer, an emitter layer, and a collector layer in the IGBT, respectively.

Each mesa part 10A includes a part of the first semiconductor layer 11, a part of the second semiconductor layer 12 located on the first semiconductor layer 11, and a part of the third semiconductor layer 13 located on the second semiconductor layer 12.

The semiconductor device 1 includes gate electrode 51, conductive members 52, first insulating film 71, and second insulating films 72. The gate electrode 51 and each conductive member 52 are next to a mesa part 10A in the direction X and extend in the direction Y. The first insulating film 71 is located between the gate electrode 51 and the mesa part 10A as well as between a lower end of the gate electrode 51 and the first semiconductor layer 11. A second insulating film 72 is located between each conductive member 52 and the mesa part 10A as well as between a lower end of the conductive member 52 and the first semiconductor layer 11. The gate electrode 51 is embedded, via the first insulating film 71, in a trench formed in the semiconductor layer 10. Each conductive member 52 is embedded, via the second insulating film 72, in a trench formed in the semiconductor layer 10. The gate electrode 51 and the conductive members 52 can be formed simultaneously from the same material in the same manufacturing step. Examples of the material of the gate electrode 51 and the conductive member 52 include polycrystalline silicon.

A side surface of the gate electrode 51 faces the second semiconductor layer 12 (base layer) of a mesa part 10A via the first insulating film 71. In the on state (gate voltage of the gate electrode 51 is higher than the threshold voltage), an n channel (inversion layer) is formed in a region of the second semiconductor layer 12 facing the gate electrode 51.

The mesa part 10A positioned between adjacent pairs of conductive members 52 is not adjacent to the gate electrode 51. Such a mesa part 10A does not have to include the third semiconductor layer 13. The mesa parts 10A not adjacent to the gate electrode 51 may include a p-type fourth semiconductor layer 14 located on the second semiconductor layer 12. The p-type impurity concentration of the fourth semiconductor layer 14 is greater than the p-type impurity concentration of the second semiconductor layer 12. The fourth semiconductor layer 14 is not facing or adjacent to the gate electrode 51.

The semiconductor device 1 further includes an insulating layer 73, a plurality of first connection portions 61, and a plurality of second connection portions 62.

The insulating layer 73 is located between the semiconductor layer 10 (mesa parts 10A) and the first electrode 20, between the gate electrode 51 and the first electrode 20, and between the conductive members 52 and the first electrode 20.

Each first connection portion 61 penetrates through the insulating layer 73 and is located between a mesa part 10A and the first electrode 20. The first connection portion 61 has electrical conductivity and electrically connects the mesa part 10A and the first electrode 20 to each other. In the mesa parts 10A including the third semiconductor layer 13, the first connection portion 61 contacts the third semiconductor layer 13 (emitter layer). The third semiconductor layer 13 is electrically connected to the first electrode 20 via the first connection portion 61. In the mesa parts 10A including the fourth semiconductor layer 14 but not including the third semiconductor layer 13, the first connection portion 61 contacts the fourth semiconductor layer 14. The fourth semiconductor layer 14 is electrically connected to the first electrode 20 via the first connection portion 61. Holes (charge carriers) in the first semiconductor layer 11 can be drained to the first electrode 20 through the second semiconductor layer 12, the fourth semiconductor layer 14, and the first connection portion 61.

Each second connection portion 62 penetrates through the insulating layer 73 and is located between the conductive member 52 and the first electrode 20. The second connection portion 62 has electrical conductivity and electrically connects the conductive member 52 and the first electrode 20 to each other. The voltage (emitter voltage) of the first electrode 20 is applied to the conductive member 52.

The first connection portion 61 and the second connection portion 62 can be formed simultaneously in the same process step of the same material. Examples of the material of the first connection portion 61 and the second connection portion 62 include tungsten.

As illustrated in FIG. 1, the first connection portion 61 extends continuously in the direction Y. On each conductive member 52, a plurality of second connection portions 62 is arranged in the direction Y. The gate electrode 51 is connected to gate wiring at an end of the gate electrode 51 in the direction Y.

A cross-sectional region illustrated in FIG. 2 includes, for example, one gate electrode 51 and three conductive members 52. The cross-sectional region illustrated in FIG. 2 is repeated a plurality of times in the direction X. Accordingly, the semiconductor device 1 includes a plurality of gate electrodes 51 and a plurality of conductive members 52. For example, the total number of conductive members 52 is greater than the total number of gate electrodes 51.

In a semiconductor device 1 having a trench-gate structure, the conductive members 52 (to which the emitter voltage is applied) are included in addition to the gate electrodes 51, leading to a reduction in gate capacitance. Furthermore, providing the conductive members 52 allows for an emitter component (gate-emitter capacitance) and a collector component (gate-collector capacitance) of the gate capacitance to be adjusted. Additionally, the conductive members 52 allows for a reduction in the channel density.

The first electrode 20 has therein a first opening 20A positioned above the conductive member 52. The first opening 20A penetrates through the first electrode 20 in the direction Z to reach the insulating layer 73. In the first opening 20A, the insulating layer 73 is exposed. Along the direction Z, a second connection portion 62 is not located between the first opening 20A and the conductive member 52.

As illustrated in FIG. 1, the first openings 20A and the second connection portions 62 are above the conductive members 52 and arranged in the direction Y along the conductive members 52.

The first electrode 20, in which metal, such as aluminum and copper, or alloys thereof, can be used, tends to have a large tensile stress, which causes warpage of a wafer before singulation (e.g., dicing) of semiconductor devices 1 from the wafer. The warpage potentially affects the conveyance (movement) and processing of the wafer.

According to the first embodiment, a first opening 20A is formed in the first electrode 20 to thereby reduce the total volume of the first electrode 20. As a result, the tensile stress of the first electrode 20 can be reduced, and thus the warpage of the wafer can be reduced.

The length (dimension) of a first opening 20A along the direction Y is less than the full length of the conductive member 52 along the direction Y and also less than the full length of the first electrode 20 in the direction Y. The first opening 20A do not divide the first electrode 20 into isolated or fully separated portions in the direction X. Each of the conductive members 52 is electrically connected to the first electrode 20 via the second connection portions 62 at positions where the first opening 20A is not present. A wire can be bonded to the first electrode 20 at the position where the first opening 20A is not present, which allows the first electrode 20 to be electrically connected to an external circuit or the like.

Referring to the example of FIG. 1, a plurality of first openings 20A and a plurality of second connection portions 62 are arranged above each conductive member 52. The first openings 20A and the second connection portions 62 are arranged above the conductive member 52 alternately along the direction Y. The conductive member 52 is electrically connected to the first electrode 20 via the second connection portion 62 in a region between first openings 20A adjacent to each other in the direction Y.

The position of the first opening 20A of a conductive member 52A (one of the two conductive members 52 adjacent to each other in the direction X) and the position of the first opening 20A of a conductive member 52B (the other of the two adjacent conductive members 52) do not align or overlap in the direction Y. Furthermore, the position of the second connection portion 62 of conductive member 52A and the position of the second connection portion 62 of conductive member 52B are different from each other in the direction Y. It should be noted that the position of the first opening 20A in the direction Y refers to the center position of the first opening 20A in the direction Y, and the position of the second connection portion 62 in the direction Y refers the center position of the second connection portion 62 in the direction Y.

As for conductive member 52B and conductive member 52C with the gate electrode 51 interposed therebetween but otherwise adjacent to each other, the first openings 20A and the second connection portions 62 of the conductive member 52B and the conductive member 52C are arranged to align (overlap) with each other along the direction X.

As illustrated in FIG. 1, the first electrode 20 may further include a second opening 20B positioned above the gate electrode 51. The second opening 20B penetrates through the first electrode 20 in the direction Z to reach the insulating layer 73. In the second opening 20B, the insulating layer 73 is exposed. For example, a plurality of second openings 20B is arranged above the gate electrode 51 along the direction Y.

The second opening 20B is formed in the first electrode 20 to thereby further reduce the volume of the first electrode 20, which makes it possible to reduce the warpage of the wafer.

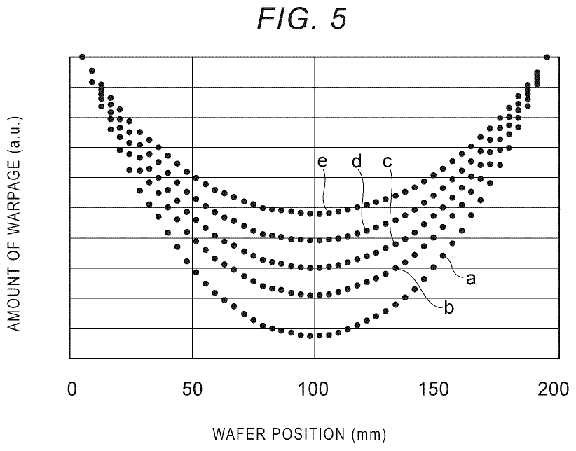

FIG. 5 is a graph showing a simulation result related to the amount of warpage of a wafer.

The diameter of the simulated wafer is set to 200 mm, and the horizontal axis represents position along a notionally planar (XY) direction of the wafer.

As for the vertical axis, the dimensionless units (arbitrary units, a.u.) as a ratio set according to the amount of warpage for sample “a” at the position of 100 mm being being considered to be equal to “1” and all other values calculated relative to this value.

The amount of warpage in each of samples (model wafers) of “a” to “e” was simulated.

In the model wafer “a”, no opening was formed in the first electrode 20.

In the model wafer “b”, the ratio of areas of an opening and a non-opening portion in the first electrode 20 was set to 3:7.

In the model wafer “c”, the ratio of areas of an opening and a non-opening portion in the first electrode 20 was set to 5:5.

In the model wafer “d”, the ratio of areas of an opening and a non-opening portion in the first electrode 20 was set to 7:3.

In the model wafer “e”, the ratio of areas of an opening and a non-opening portion in the first electrode 20 was set to 9:1.

FIG. 5 shows that the higher the ratio of area of the opening in the first electrode 20, the smaller the amount of warpage.

### Second Embodiment

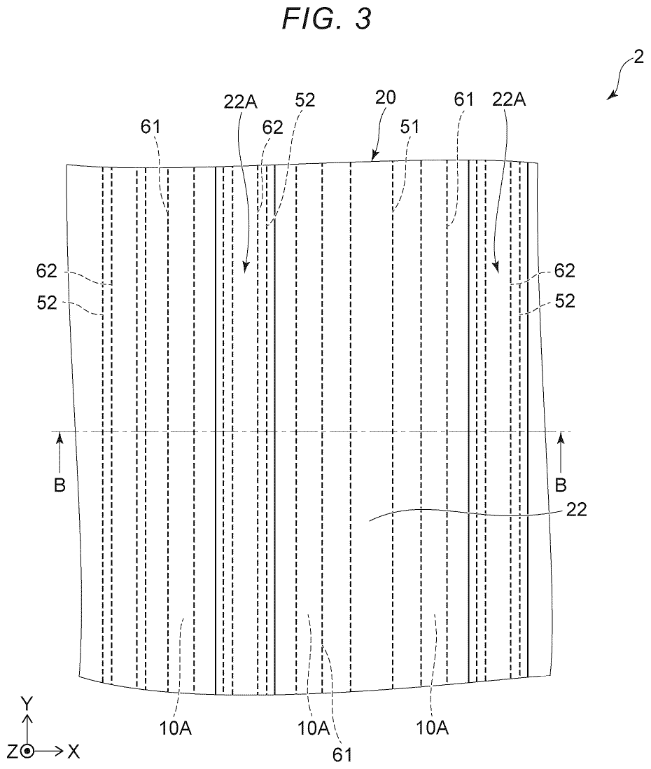

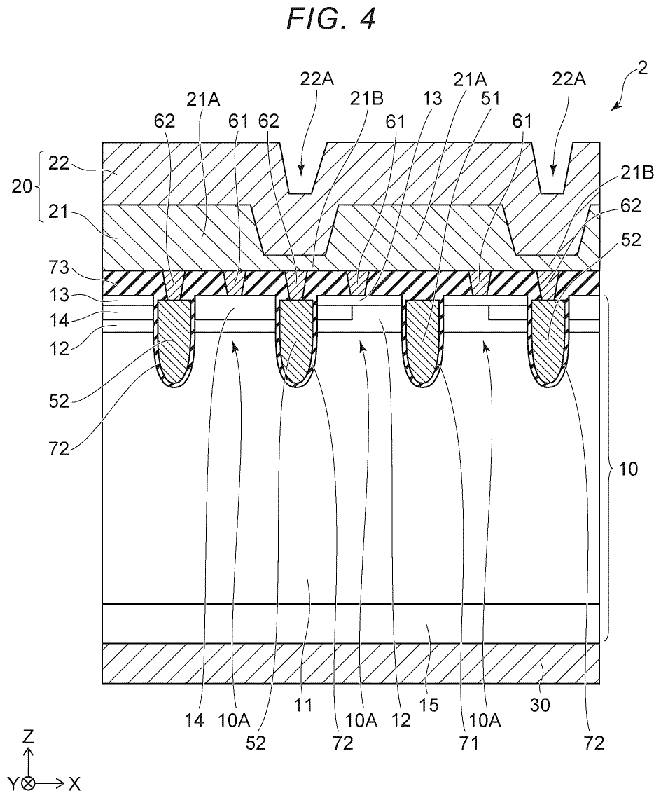

A semiconductor device 2 according to the second embodiment will be described with reference to FIGS. 3 and 4. In semiconductor device 2 according to the second embodiment, those aspects that are the same (or substantially so) as those of a semiconductor device 1 according to the first embodiment are denoted by the same reference symbols. The description of the second embodiment mainly focuses on aspects different from those of the first embodiment.

The first electrode 20 includes a first layer 21 located on the insulating layer 73 and a second layer 22 located on the first layer 21. The first connection portions 61 penetrate through the insulating layer 73. The first connection portions are located between a mesa part 10A and the first layer 21 and contact the mesa part 10A and the first layer 21. The second connection portions 62 penetrate through the insulating layer 73. The second connection portions 62 are located between a conductive member 52 and the first layer 21 and contact the conductive member 52 and the first layer 21. Examples of the material of the first layer 21 include aluminum and copper. Examples of the material of the second layer 22 include nickel.

The first layer 21 includes a first portion 21A and a second portion 21B. The second portion 21B has a thickness (dimension in the direction Z) smaller than the thickness (dimension in the direction Z) of the first portion 21A. The second portion 21B is positioned above the conductive member 52. The upper surface of the first layer 21 is uneven. The second layer 22 is located on the first layer 21 and as a corresponding unevenness matching the upper surface of the first layer 21 in planar (XY) position. The second layer 22 thus has a recess 22A positioned above the second portion 21B. As illustrated in FIG. 3, the second portion 21B and the recess 22A extend longitudinally in the direction Y. A wire can be bonded to the first electrode 20 at a position where the recess 22A is not present, which allows the first electrode 20 to be electrically connected to an external circuit.

The total volume of the first electrode 20 can be reduced (lower) because of the recess 22A in the second layer 22. As a result, the tensile stress produced by the first electrode 20 can be reduced, and the warpage of the wafer can be reduced.

The second layer 22 can be formed by plating. When a through portion (e.g., a hole or trench) is formed in the first layer 21 to reduce the volume of the first electrode 20, there is a concern that when insulating layer 73 is left exposed by the through portion, ions in the plating solution will pass into or through the insulating layer 73 during the plating process towards a cell portion side where the mesa part 10A and the gate electrode 51 are formed. This ion inflow may reduce the reliability of the semiconductor device.

According to the second embodiment, the second portion 21B still remains and thus a portion of the first layer 21 remains to cover the insulating layer; therefore, the insulating layer 73 is not left exposed during the plating process for forming the second layer 22. This prevents ions in the plating solution from moving into the cell portion side through the insulating layer 73.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first electrode;
a second electrode;
a semiconductor layer between the first electrode and the second electrode, the semiconductor layer including a plurality of mesa parts spaced from each other in a first direction;
an insulating layer between the first electrode and the semiconductor layer;
a gate electrode adjacent in the first direction to a first mesa part in the plurality of mesa parts and extending lengthwise in a second direction perpendicular to the first direction;
a first conductive member adjacent in the first direction to the first mesa part, the first mesa part being between the gate electrode and the first conductive member in the first direction and extending lengthwise in the second direction;
a first connector between the first electrode and the first mesa part at a first position along the second direction and electrically connecting the first electrode and the first mesa part; and
a second connector between the first electrode and the first conductive member at a second position along the second direction and electrically connecting the first electrode and the first conductive member, wherein
the first electrode has a first recess above the first conductive member at the first position along the second direction, and
the first position and the second position are offset from each other in the second direction.

2. The semiconductor device according to claim 1, further comprising:
a second conductive member adjacent in the first direction to a second mesa part in the plurality of mesa parts, the second mesa part being between the first conductive member and the second conductive member in the second direction.

3. The semiconductor device according to claim 1, wherein a plurality of the first recesses and a plurality of second connectors are alternatingly arranged along the first conductive member in the second direction.

4. The semiconductor device according to claim 1, wherein the first electrode further includes a second recess above the gate electrode, second recess is at the second position along the second direction and reaches the insulating layer.

5. The semiconductor device according to claim 4, wherein a plurality of second openings are spaced from each other in the second direction along the gate electrode.

6. The semiconductor device according to claim 1, wherein the first mesa part includes:
a first semiconductor layer of a first conductivity type,
a second semiconductor layer of a second conductivity type on the first semiconductor layer, and
a third semiconductor layer of the first conductivity type on the second semiconductor layer, the third semiconductor layer having a first conductivity type impurity concentration greater than that of the first semiconductor layer,
the first connector contacts the third semiconductor layer, and
a side surface of the gate electrode faces the second semiconductor layer.

7. The semiconductor device according to claim 6, wherein
the first mesa part further includes a fourth semiconductor layer of the second conductivity type, the fourth semiconductor layer being on the second semiconductor layer and having a second conductivity type impurity concentration greater than that of the second semiconductor layer, and
the first connector contacts the fourth semiconductor layer.

8. The semiconductor device according to claim 7, wherein the semiconductor layer further includes a fifth semiconductor layer of the second conductivity type, the fifth semiconductor layer being between the second electrode and the first semiconductor layer.

9. The semiconductor device according to claim 1, wherein the first recess of the first electrode reaches the insulating layer.

10. The semiconductor device according to claim 1, further comprising:
a first insulating film between the gate electrode and the semiconductor layer; and
a second insulating film between the first conductive member and the semiconductor layer.

11. The semiconductor device according to claim 1, wherein
the first electrode includes a first layer and second layer, and
the first layer contacts the insulating layer in the first recess.

12. A semiconductor device, comprising:
a first electrode;
a second electrode;
a semiconductor layer between the first electrode and the second electrode, the semiconductor layer including a plurality of mesa parts spaced from each other in a first direction;
an insulating layer between the first electrode and the semiconductor layer;
a gate electrode adjacent in the first direction to a first mesa part in the plurality of mesa parts and extending lengthwise in a second direction perpendicular to the first direction;
a first conductive member adjacent in the first direction to the first mesa part, the first mesa part being between the gate electrode and the first conductive member in the first direction and extending lengthwise in the second direction;
a first connector between the first electrode and the first mesa part at a first position along the second direction and electrically connecting the first electrode and the first mesa part; and
a second connector between the first electrode and the first conductive member at a second position along the second direction and electrically connecting the first electrode and the first conductive member, wherein
the first electrode includes a first layer on the insulating layer and a second layer on the first layer,
the first layer includes a: first portion and a second portion, the second portion being above the first conductive member at the second position in the second direction and having a thickness less than that of the first portion above the first conductive member at the first position in the second direction, and
the second layer has a recessed portion above the second portion of the first layer.

13. The semiconductor device according to claim 12, wherein the second portion and the recessed portion extend in the second direction toward the first position.

14. The semiconductor device according to claim 12, wherein the first mesa part includes:
a first semiconductor layer of a first conductivity type,
a second semiconductor layer of a second conductivity type on the first semiconductor layer, and
a third semiconductor layer of the first conductivity type on the second semiconductor layer, the third semiconductor layer having a first conductivity type impurity concentration greater than that of the first semiconductor layer,
the first connector contacts the third semiconductor layer, and
a side surface of the gate electrode faces the second semiconductor layer.

15. The semiconductor device according to claim 14, wherein the first mesa part further includes:
a fourth semiconductor layer of the second conductivity type, the fourth semiconductor layer being on the second semiconductor layer and having a second conductivity type impurity concentration greater than that of the second semiconductor layer, and
the first connector contacts the fourth semiconductor layer.

16. The semiconductor device according to claim 14, wherein the semiconductor layer further includes a fifth semiconductor layer of the second conductivity type, the fifth semiconductor layer being between the second electrode and the first semiconductor layer.

17. A semiconductor device, comprising:
a first electrode;
a second electrode;
a semiconductor layer between the first electrode and the second electrode, the semiconductor layer including a plurality of mesa parts spaced from each other in a first direction;
an insulating layer between the first electrode and the semiconductor layer;
a gate electrode adjacent in the first direction to a first mesa part in the plurality of mesa parts and extending lengthwise in a second direction perpendicular to the first direction;
a first conductive member adjacent in the first direction to the first mesa part, the first mesa part being between the gate electrode and the first conductive member in the first direction and extending lengthwise in the second direction;
a first connector between the first electrode and the first mesa part at a first position along the second direction and electrically connecting the first electrode and the first mesa part; and
a second connector between the first electrode and the first conductive member at a second position along the second direction and electrically connecting the first electrode and the first conductive member, wherein
the first electrode has a first opening above the first conductive member at the first position along the second direction, and
the first position and the second position are offset from each other in the second direction.

18. The semiconductor device according to claim 17, further comprising:
a second conductive member adjacent in the first direction to a second mesa part in the plurality of mesa parts, the second mesa part being between the first conductive member and the second conductive member in the second direction.

19. The semiconductor device according to claim 17, wherein a plurality of the first openings and a plurality of second connectors are alternatingly arranged along the first conductive member in the second direction.

20. The semiconductor device according to claim 17, wherein the first electrode further includes a second opening above the gate electrode, second opening is at the second position along the second direction and reaches the insulating layer.
